(19) United States
(12) Patent Application Publication
(10) Pub. No.: US 2016/0300999 A1
(43) Pub. Date: Oct. 13, 2016

(54) Magnetoresistive Random Access Memory Cell

(71) Applicants: Ge Yi, San Ramon, CA (US); Zhanjie Li, Pleasanton, CA (US)

(72) Inventors: Ge Yi, San Ramon, CA (US); Zhanjie Li, Pleasanton, CA (US)

(73) Assignees: Ge Yi, San Ramon, CA (US); Zhanjie Li, Pleasanton, CA (US)

(21) Appl. No.: 14/680,073

(22) Filed: Apr. 7, 2015

(51) Int. Cl. H01L 43/02; H01L 43/08; G11C 11/16

(52) U.S. Cl. CPC H01L 43/02; G11C 11/161; H01L 43/08

(57) ABSTRACT

A novel three-terminal MRAM memory cell with an independent sensing and writing paths, a composite data storage layer together with a bias magnetic field for the data storage layer has been invented. The interaction between the magnetic layers within the composite data storage layer is either via Ruderman-Kittel-Kasuya-Yosida (RKKY) coupling, or magnetostatic coupling, or orange peel coupling, or even a direct ferromagnetic coupling. The design improves magnetic and thermal stability of the cell, thus capable for higher area density.

### RELATED APPLICATIONS

The present application claims of the priority benefit of U.S. 62/108,071—a provisional patent application—directly related. The present application also claims of the priority benefit of two previous applications: firstly, U.S. patent application Ser. No. 13/288,860 filed on Nov. 3, 2011 as utility application, published on May 9, 2013 as US2013/0114334A1 entitled “MAGNETORESISTIVE RANDOM ACCESS MEMORY CELL WITH INDEPENDENTLY OPERATING READ AND WRITE COMPONENTS”; secondly, U.S. patent application Ser. No. 14/506,618 filed on Nov. 4, 2014 as utility application entitled “MAGNETORESISTIVE RANDOM ACCESS MEMORY CELL and 3D MEMORY CELL ARRAY”; which are incorporated herein by reference.

### FIELD OF INVENTION

The invention is related to magnetoresistive random access memory cell design. Particularly, the so-called spin-orbit torque magnetoresistive random access memory (SOT-MRAM) cell design for improving its thermal and magnetic stability.

### BACKGROUND ART

Data storage memory is one of the backbones of the modern information technology. Semiconductor memory in the form of Dynamic Random-Access Memory (DRAM), Static Random-Access Memory (SRAM) and flash memory has dominated the digital world for the last forty years. Comparing to DRAM based on transistor and capacitor above the gate of the transistor, SRAM using the state of a flip-flop with large form factor is more expensive to produce but generally faster and less power consumption. Nevertheless, both DRAM and SRAM are volatile memory, which means they lost the information stored once the power is removed. Flash memory on the other hand is non-volatile memory and cheap to manufacture. However, flash memory has limited endurances of writing cycle and slow write though the read is relatively faster.

Magnetoresistive random access memory (MRAM) is relatively a new type of memory technology. It has the speed of the SRAM, density of the DRAM and it is non-volatile as well. If it is used to replace the DRAM in computer, it will not only give “instant on” but “always-on” status for operation system, and restore the system immediately to the point when the system is power off. It could provide a single storage solution to replace separate cache (SRAM), memory (DRAM) and permanent storage (hard disk drive (HDD) or flash-based solid state drive (SSD)) on portable device at least. Considering the rapid growth of “cloud computing” technology, MRAM has a great potential and can be the key dominated technology in digital world.

MRAM stores the informative bit “1” or “0” into the two magnetic states in the so-called magnetic storage layer. The different states in the storage layer gives two distinctive voltage outputs from the whole memory cell, normally a patterned tunneling magnetoresistive (TMR) stack structure. The TMR stack structure provides a read out mechanism sharing the same well-understood physics as current magnetic reader used in conventional hard disk drive.

There are two kinds of mostly developed MRAM technologies based on the write process: one kind, which can be labeled as the conventional magnetic field switched (toggle) MRAM, uses the magnetic field induced by the current in the remote write line to change the magnetization orientation in the data stored magnetic layer from one direction (for example “1”) to another direction (for example “0”). This kind of MRAM has more complicated cell structure and needs relative high write current (in the order of mA). It has poor scalability beyond 65 nm because the write current in the write line needs to continue increase to ensure reliable switching the magnetization of the magnetic storage layer because of the fact that the smaller the physical dimension of the storage cell, the higher the magnetic coercivity it normally has for the same material. Nevertheless, the only commercially available MRAM so far is based on this conventional writing scheme. The other kind of the MRAM is called as a spin-transfer torque (STT) switching MRAM. It is believed that the STT-RAM has much better scalability due to its simple memory cell structure. While the data read out mechanism is still based on TMR effect, the data write is governed by physics of spin-transfer effect. Despite of intensive efforts and investment, even with the early demonstrated by Sony in late 2005, no commercial products are available on the market so far. One of the biggest challenges of STT-RAM is its reliability, which depends largely on the value and statistical distribution of the critical current density needed to flip the magnetic storage layers within every patterned TMR stack used in the MRAM memory structures. Currently, the value of the critical current density is in the range of 10⁶ A/cm². To allow such a large current density to flow through the dielectric barrier layer such as AlOx and MgO in the TMR stack, the thickness of the barrier has to be relatively thin for writing energy reduction; however such a thin barrier not only limits the magnetoresist (MR) ratio value but also causes potential risk of the barrier breakdown. As such, a large portion of efforts in developing the STT-RAM is focused on lowering the critical current density while maintaining the thermal stability of the magnetic data storage layer.

More recently, a new class of MRAM cell design named Spin-orbit Torque Magnetic Random Access Memory (SOT-RAMR) has been proposed using so-called spin-orbit torque (SOT) interaction to flip the storage layer within a TMR stack (G. Yi et. al. US2013/0114334A1). The new class of SOT-MRAM cell is a three terminator device with separated write and read paths. The storage layer of the memory cell is sandwiched between a heavy metal layer and dielectric layer to facilitate spin-orbit torque.

The spin-orbit torque effect is capable of flipping magnetic layers with either perpendicular anisotropy or in-plane anisotropy film, which has been demonstrated in the literature (I. M. Miron et. al., Nature, vol. 476, 189, (2011). “perpendicular switching of a single ferromagnetic layer induced by in-plane current injection”; L. Liu et. al., Science vol. 336, 555, (2012), “Spin-torque switching with the giant spin Hall effect of Tantalum”.). However, when SOT effect is used to design magnetic memory cell, there is still a lot of challenges.

First of all, the spin-orbit torque is an interfacial effect. Therefore, the thicker the storage layer, the higher the critical current density needed to flip the storage layer. As such, a thinner storage layer is much more desired from switching current density reduction point of view. Unfortunately, as the size of the memory cell (i.e. the footprint of the storage layer: S) is reduced, with a thin storage layer (with thickness of t), the thermal stability of the storage layer is in serious doubt because of the thermal stability factor KV/k_{B}T being proportion to the total magnetic volume (V=S*t) of storage layer (K is magnetic anisotropy of storage layer, S is the cross section of storage layer, t is the thickness of storage layer, k_{B} is the Boltzmann, T is the temperature in absolute temperature unit).

For memory cell design based on perpendicular storage layer (or perpendicular TMR stack), even without considering the magnitude of current density for the SOT effect, there are some practical challenges. For example, for available CoFeₓB₂₀/MgO/CoFeₓB₂₀ TMR stack showing high TMR ratio, once the thickness of the simple single storage layer CoFeₓB₂₀ is larger than ˜1.5 nm or slightly more, the orientation of its magnetization stays in-plane of film growth plane rather than much needed perpendicular pointing. In fact, from the literature, it is believed that the perpendicular magnetization of simple single CoFeₓB₂₀ layer is more repeatable when its thickness is around one nanometer.

The memory cell design based on an in-plane storage layer (or in-plane TMR stack) can have a thicker CoFeₓB₂₀ storage layer for available CoFeₓB₂₀/MgO/CoFeₓB₂₀ TMR stack showing high TMR ratio. However, the in-plane TMR stack based MRAM cell design, in general, has its own unresolved issue, i.e., the magnetic interaction between the adjacent cells due to fringe magnetic field from the storage layers causing instability and wide spread of the switching current density variation. Moreover, the thicker the storage layer, the worse the inter-cell magnetic cross-talk as well as the larger the critical current density needed for SOT to flip the storage layer.

It is well known that one of the biggest advantages of having a perpendicular TMR stack as a MRAM cell is to increase its magnetic stability by minimizing the magnetic interaction between the adjacent cells. This is very much similar to the advantages achieved when magnetic recording medium converted from the longitudinal magnetic medium to current perpendicular magnetic medium by eliminating the magnetic interacting between the adjacent bits. In other words, a perpendicular-TMR-stack based memory cell is preferred compared with in-plane-TMR-stack based design unless the magnetic interaction between the fringe field emitted from the storage layer of the in-plane-TMR-stack based memory cell can be mitigated.

In this disclosure, we provide novel SOT-MRAM cell designs to resolve the above mentioned issues for both perpendicular-TMR based cell and in-plane TMR based cell design.

### SUMMARY OF THE INVENTION

In this invention, a novel design for SOT-MRAM is proposed. The core structure of such a design is to have a complementary magnetic stabilization layer placed very close to the magnetic storage layer.

The complementary magnetic stabilization layer can be either built as part of the TMR stack (case I) or electrically and magnetically isolated from the magnetic storage layer and placed out of the TMR stack of the cell (Case II). The complementary magnetic stabilization layer interacts with the magnetic storage layer via Ruderman-Kittel-Kasuya-Yosida (RKKY) coupling, or magnetostatic coupling, or orange peel coupling (roughness induced ferromagnetic coupling when the non-magnetic layer is very thin), or even direct ferromagnetic coupling (when the non-magnetic separation ‘layer’ is below or around few atomic layers e.g. <˜0.8 nm, particularly for Case I).

For both cases, a particular structure, which provides a lateral magnetic bias field, is placed either in the stack or close to the stack to assist the switching of the magnetic storage layer and to low the critical switching current (or current density).

For Case I, the complementary magnetic layer and the magnetic storage layer forms a composite free layer for data storage. As to in-plane TMR based SOT-MRAM cell, this composite free layer is a synthetically antiferromagnetic (SAF) structure or magnetostatic coupling antiferromagnetic oriented structure. The purpose is to form a closed flux loop for their edge magnetic charge to fully or partially cancel magnetic flux emitting from the cell. For partially canceling of edge magnetic charge, the two ferromagnetic layers can have unbalance magnetic moment, which can be achieved either through different layer thickness for two ferromagnetic layers in the SAF structure, or layers with same thickness but different magnetic materials thus different moments, or both. For perpendicular TMR based SOT-MARM cell, the composite free layer is configured into ferromagnetic coupling through RKKY, or orange peel coupling, or direct ferromagnetic coupling to reduce de-magnetic field and increases the thermal stability of magnetic storage layer by increase effective thickness of the magnetic data storage layer. In some case, it also helps to greatly boost the TMR ratio of the TMR stack used in the SOT-MRAM cell. For TMR stack, the preferred choice of the materials for introducing ferromagnetic RKKY coupling is Pt, β-W and β-Ta, which also helps to switch the composite free layer for data storage due to SOT effects on both layers within the composite free layer. Examples of the composite free layer for data storage is Co (or CoFe₄₀₋₆₀B₂₀) 0.2-1.2 nm/Pt (or Ta, or W) 0.1-1.0 nm or 4-9 nm/Co 0.2-1.2 nm (optional)/CoFe₄₀₋₆₀B₂₀) 0.4-1.2 nm, while the whole stack is as below: Co (or CoFe₄₀₋₆₀B₂₀) 0.2-1.2 nm/Pt(or Ta, or W) 0.1-1.0 nm or 4-9 nm/Co 0.2-1.2 nm (optional)/CoFe₄₀₋₆₀B₂₀ 0.4-1.2 nm/MgO 1.5 nm-10 nm/CoFe₄₀₋₆₀B₂₀ 0.4-1.2 nm /(Co 0.4 nm/Pt 0.5 nm)₂₋₅/(optional Ru antiferromagnetic thickness)/(optional (Co 0.4 nm/Pt 0.5 nm)₂₋₅)/(optional IrMn 4-8 nm)/seed layer 6 nm.

For the Case II, the complementary magnetic layer and its distance from the storage layer is engineered in such a way that the magnetic field emitting from the storage layer is capable of leaving a matched magnetic footprint within the magnetic layer. The interaction between the magnetic footprint and the magnetic storage layer leads a huge benefits, particularly for in-plane TMR stack based MRAM cell designs.

### BRIEF DESCRIPTION OF THE DRAWINGS

FIG. 1A illustrates one embodiment of the proposed SOT-MRAM cells based on perpendicular TMR stack locating at the bottom of the cell structure, together with an in-stack magnet providing a magnetic field bias.

FIG. 1B illustrates one embodiment of the proposed SOT-MRAM cells based on perpendicular TMR stack locating on the top of the cell structure, together with an in-stack magnet providing a magnetic field bias.

FIG. 2A illustrates one embodiment of the proposed SOT-MRAM cells based on perpendicular TMR stack locating at the bottom of the cell structure, together with side bias magnet along the leads of the cell for providing bias field and reducing the lead resistance.

FIG. 2B illustrates one embodiment of the proposed SOT-MRAM cells based on perpendicular TMR stack locating on the top of the cell structure, together with side bias magnet along the leads (can be place either on top or at the bottom of leads) of the cell for providing bias field and reducing the lead resistance.

FIG. 3A illustrates one embodiment of the proposed SOT-MRAM cells based on in-plane TMR stack locating at the bottom of the cell structure, with the easy axis of all its magnetic layers in-plane and normal to the switching current direction.

FIG. 3B illustrates one embodiment of the proposed SOT-MRAM cells based on in-plane TMR stack locating on the top of the cell structure, with the easy axis of all its magnetic layers in-plane and normal to the switching current direction.

FIG. 4A illustrates one embodiment of the proposed SOT-MRAM cells based on in-plane TMR stack locating at the bottom of the cell structure, with the easy axis of all its magnetic layers in-plane and normal to the switching current direction, together with side bias magnet along the leads of the cell for providing bias field and reducing the lead resistance.

FIG. 4B illustrates one embodiment of the proposed SOT-MRAM cells based on in-plane TMR stack locating at the top of the cell structure, with the easy axis of all its magnetic layers in-plane and normal to the switching current direction, together with side bias magnet along the leads of the cell for providing bias field and reducing the lead resistance.

FIG. 5 illustrates the embodiment of memory cell structure, which includes all of the common features for the embodiments shown in designs from FIG. 1A to FIG. 4B.

### DETAILED DESCRIPTION

The following description is provided in the context of particular designs, applications and the details, to enable any person skilled in the art to make and use the invention. However, for those skilled in the art, it is apparent that various modifications to the embodiments shown can be practiced with the generic principles defined here, and without departing the spirit and scope of this invention. Thus, the present invention is not intended to be limited to the embodiments shown, but is to be accorded the widest scope consistent with the principles, features and teachings disclosed here.

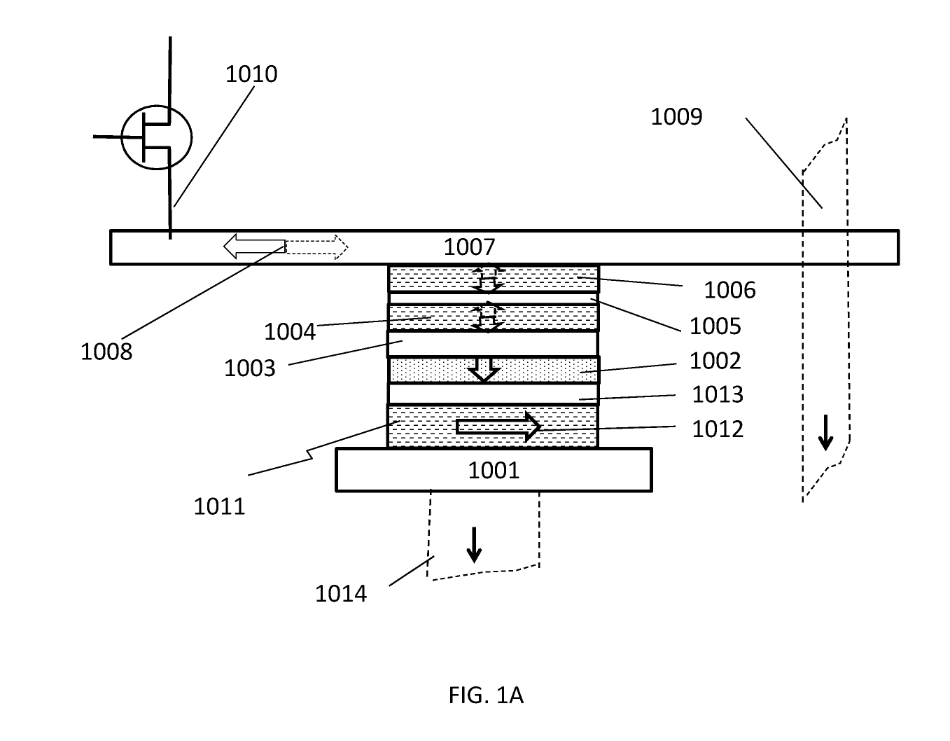

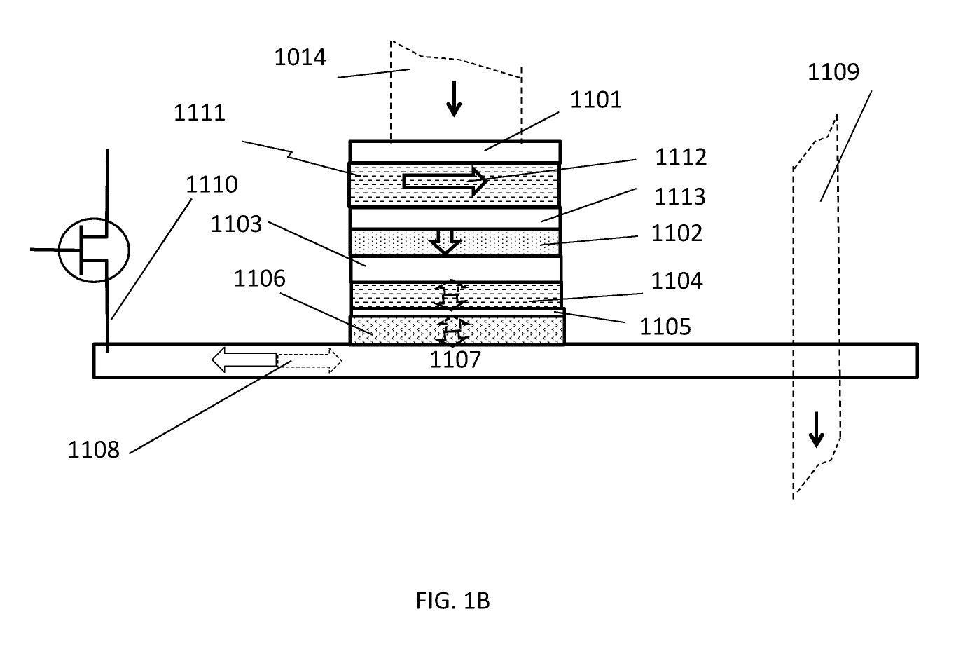

FIG. 1A illustrates one embodiment of the proposed SOT-MRAM cells based on perpendicular TMR stack locating at the bottom of the cell structure, together with an in-stack magnet providing a magnetic field bias to storage layer along the switching current direction. The in-stack bias magnet is just an optional, which helps to low the switching/write current of the cell. In the following context, it will be seen that the location of the magnet for providing such a bias can vary. As shown in FIG. 1A, the whole SOT-MRAM cell is built on bottom lead and seed layer 1001, which is linked to read current/voltage supplier and read control electronics 1014. An in-stack bias magnet 1011, which can be made of either a hard magnetic material, such as CoPt with corresponding seed layer or a soft-magnetic/antiferromagnetic bilayer such as CoFe/IrMn, whose magnetization is shown by arrow 1012 at the lateral direction along the direction of the switching current 1008. The end magnetic charge of the in-stack bias layer 1011 provides a magnetic field bias to the storage layer 1004 in the direction along the switching current direction. A non-magnetic metal insertion, 1005 inserted between perpendicular data storage layer 1004 and perpendicular magnetic stabilization layer 1006. The reference layer(or layer structure) 1002 with fixed magnetization direction as shown by single-pointing arrow, the tunneling barrier layer 1003 and composite structure including stabilization layer 1006, insertion 1005, and storage layer 1004, with the double-pointing arrows, forms the basic perpendicular TMR structure for the cell. Over the layer 1006 is the switching current lead 1007, which is made of metal capable of introducing large SOT effects such as those with large Magnetic Hall Effects, e.g. β-Ta, β-W, Pt, Ir, Os, Re, Hf, Pd, Rh, Mo, Nb, Zr, Au, Tc, Cd, Pb, Sn, or their alloys. The current lead 1007 links at one end to cell access/selection electronics 1010 and at the other end to the writing current supplier and control electronics 1009. The insertion 1005 can be a continue layer capable of introducing ferromagnetic RKKY coupling between layers 1004 and 1006. 1005 also can be a very thin and rough layer or even a broken layer such as Ta, W or Pt below 0.8 nm, which depends on either orange peel coupling or direct ferromagnetic coupling through broken layer between 1004 and 1006 layer to ensure the magnetization within layer 1004 and 1006 follow each other at the same direction at any given time. Such a design effectively increases the total thickness of the data storage layer, which not only greatly increase the thermal stability of the data storage layer, but also is potentially capable of increasing the TMR ratio of the perpendicular TMR stack. With the material of the insertion layer is chosen to be similar to the material of the metal layer with large SOT effects, the SOT switching current used to flip the cell is not necessary to increase even with effective thickness increase for the data storage layer. When the insertion 1005 is below a continue layer (e.g <0.8 nm), the structure of 1005 and 1006 can be repeatable a couple of time to further increase of the effective thickness of the data storage layer while maintaining the perpendicular magnetic orientation of the whole composite layer structure. For example, the whole composite structure can be as CoFe₆₀B₂₀ 0.8 nm/Ta (or W) 0.3 nm/CoFe₆₀B₂₀ 0.8 nm/Ta (or W) 0.3 nm/CoFe₆₀B₂₀ 1 nm/MgO (tunneling barrier)/Pin layer.

During write process, when the switching current 1008 changes from left to right and or vice versa, the magnetization of the layer 1006 is changed accordingly based on SOT effect. Since the 1006 is closely ferro-magnetically coupled with data storage layer 1004, the magnetization of the data storage layer 1004 is also switched accordingly, hence the information stored within the SOT-MRAM cell. During the read process, the reading current through the SOT-MRAM cell from lead 1014 to top lead 1007 through tunneling barrier 1003. The relative magnetization orientation between the fixed magnetic reference layer 1002 and composite layer compositing structure (including 1004, 1005 and 1006) determinates the output voltage from the cell either high or low, which is used to figure out the storage magnetic bit within the particular cell.

FIG. 1B illustrates one embodiment of the proposed SOT-MRAM cells based on perpendicular TMR stack locating on the top of the cell structure, together with an in-stack magnet providing a magnetic field bias to storage layer along the switching current direction. As shown in FIG. 1B, the whole SOT-MRAM cell is built on bottom lead and seed layer 1107, which is linked to cell access control electronics 1110 and writer control and current/voltage supply electronics 1109. On top of the 1107 is the cell's perpendicular magnetic stabilization layer 1105 separated from data storage layer 1104 by a non-magnetic insertion 1105. The 1106, 1105, and 1104 form the composite free layer structure. Over 1104 is the magnetic tunneling barrier 1103 made of dielectric materials such as MgO, over which is the pinned perpendicular magnetic reference layer 1102. Over the pinned layer 1102 is a non-magnetic metallic layer 1113, which separates the in-stack in-plane bias structure 1111 from the pinned magnetic layer 1102. The 1111 has a non-magnetic capping layer to protect it from wafer process, which also links to the external reading current supply 1014. The bias layer (or structure) 1111 has its magnetization 1112 pointing closely parallel to the switching current direction 1108 to reduce the flipping current (or current density) needed to the flip the magnetization of the composite structure.

The switching current carrying lead 1107 made of metal with large SOT-effect (or large magnetic Hall effect) such as β-Ta, β-W, Pt, Ir, Os, Re, Hf, Pd, Rh, Mo, Nb, Zr, Au, Tc, Cd, Pb, Sn, or their alloys. The in-stack bias magnet 1112, which can be made of either a hard magnetic material, such as CoPt with corresponding seed layer or a soft-magnetic/antiferromagnetic bilayer such as CoFe/IrMn. The insertion 1105 can be a continue layer capable of introducing ferromagnetic RKKY coupling between layers 1104 and 1106. 1105, also can be a very thin and rough layer or even a broken layer such as Ta, W or Pt below 0.6 nm, which depends on either orange peel coupling or direct ferromagnetic coupling through broken layer between 1104 and 1106 layer to ensure the magnetization within layer 1104 and 1106 follow each other at the same direction under any circumstance. Such a design effectively increases the total thickness of the data storage layer, which not only greatly increase the thermal stability of the data storage layer, but also is potentially capable of increasing the TMR ratio of the perpendicular TMR stack. When the insertion 1105 is below few atomic layers (e.g <0.8 nm), the structure of 1105 and 1106 can be repeatable a couple of time to further increase of the effective thickness of the data storage layer while maintaining the perpendicular magnetic orientation of the whole composite layer structure. For example, the whole composite structure can be as Pin layer/MgO (tunneling barrier)/CoFe₆₀B₂₀ 1 nm/Ta (or W) 0.2 nm/CoFe₆₀B₂₀ 0.8 nm/Ta (or W) 0.2 nm/CoFe₆₀B₂₀ 0.8 nm.

The composite data storage layer switching or cell writing process and read process are all similar to what has been described for FIG. 1A. For any skilled people in the field, it is easy to tell the similarity between the cell design in FIG. 1A and FIG. 1.B. Therefore, there is no need for the extra description here for cell's writing and reading processes.

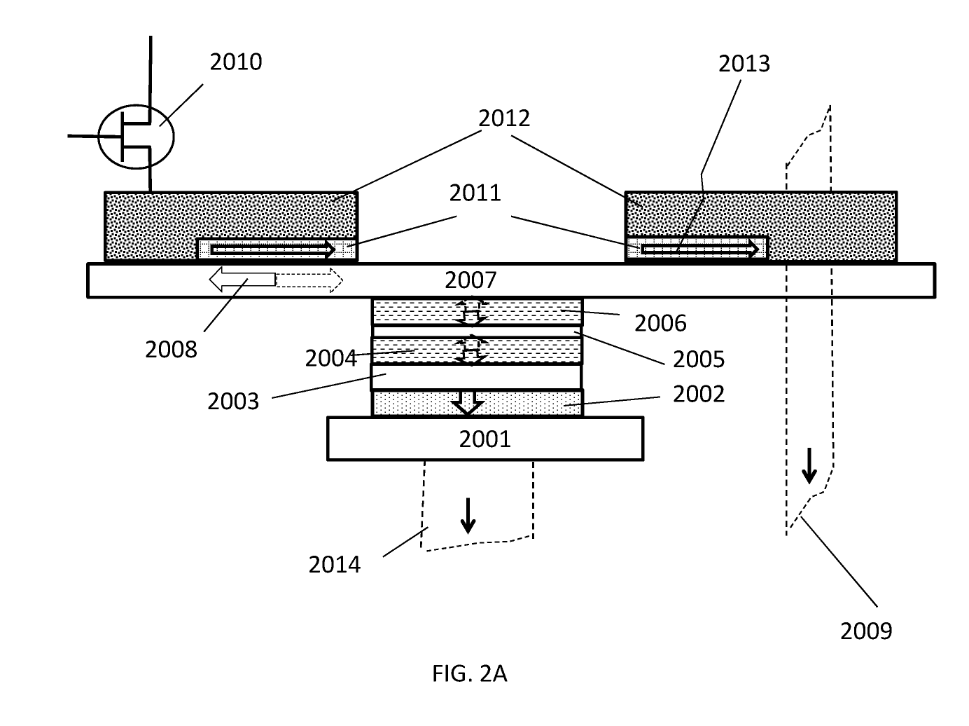

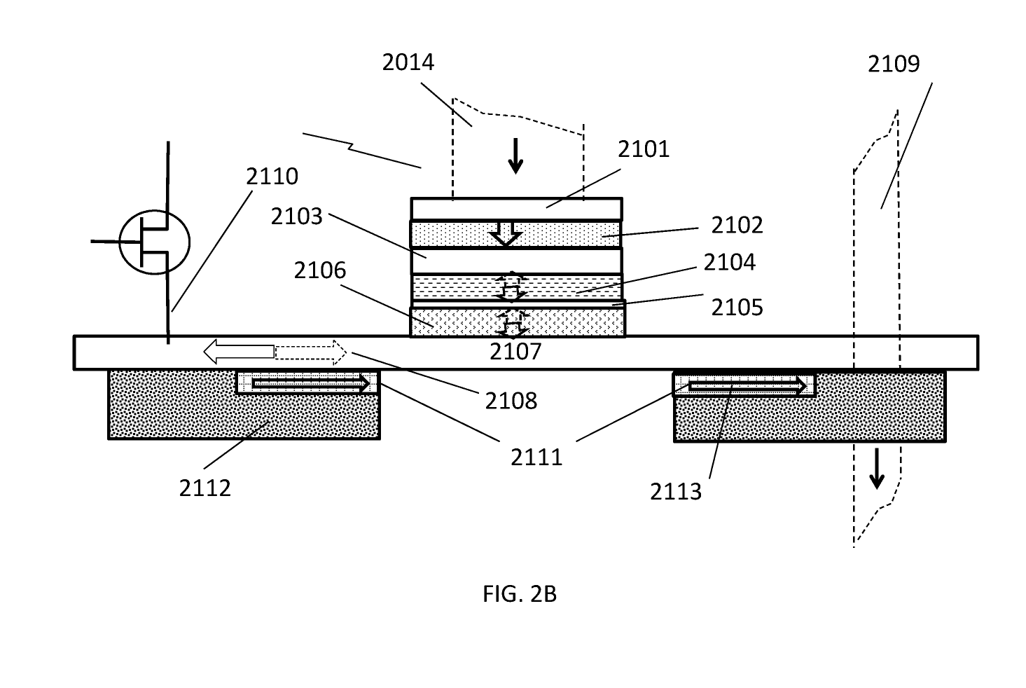

FIG. 2A illustrates one embodiment of the proposed SOT-MRAM cells based on perpendicular TMR stack locating at the bottom of the cell structure, together with side bias magnet along the leads of the cell for providing bias field and reducing the lead resistance. The stack is very much similar to cell stack in FIG. 1A but without the in-stack bias magnet 1011. Instead, it has a side bias 2011 adjacent to the cell. As shown in FIG. 2A, the whole SOT-MRAM cell is built on bottom lead and seed layer 2001, which is linked to read current/voltage supplier and read control electronics 2014. On top of the 2001 is the magnetization-fixed (represent here by single-pointing arrow) perpendicular reference layer or layer structure 2002. Although only one layer 2002 is shown here, layer 2002 can have much more complicated structure. 2003 is the tunneling barrier of the TMR stack, normally made of MgO. Over the tunneling barrier, there is a composite structure comprising perpendicular data storage layer 2004, non-magnetic metal insertion 2005 and perpendicular magnetic stabilization layer 2006. Layer 2004 and 2006 all have the double-pointing arrow, which means their magnetization can be switched between two opposite directions. Over the layer 2006 is the switching current lead 2007, which is made of metal capable of introducing large SOT effects such as those with large Magnetic Hall Effects, e.g. β-Ta, β-W, Pt, Ir, Os, Re, Hf, Pd, Rh, Mo, Nb, Zr, Au, Tc, Cd, Pb, Sn, or their alloys. The current lead 2007 links at one end to cell access/selection electronics 2010 and at the other end to the writing current supplier and control electronics 2009. Over the lead 2007, on both side of the cell structure, there are bias magnets 2011 with its magnetization 2013 pointing along the direction of switching current 2008. Over the 2011 are highly conductive assistant leads 2012, which help to reduce the lead resistance.

The insertion 2005 can be a continue layer capable of introducing ferromagnetic RKKY coupling between layers 2004 and 2006. 2005 also can be a very thin and rough layer or even a broken layer such as Ta, W or Pt below 0.8 nm, which depends on either orange peel coupling or direct ferromagnetic coupling through broken atomic layer between 2004 and 2006 layer to ensure the magnetization within layer 2004 and 2006 follow each other at the same direction at any given time. Such a design effectively increases the total thickness of the data storage layer, which not only greatly increase the thermal stability of the data storage layer, but also is potentially capable of increasing the TMR ratio of the perpendicular TMR stack, including reference layer 2002, tunneling barrier 2003 and composite layer structure including 2004, 2005 and 2006. With the material of the insertion layer is chosen to be similar to the material of the metal layer with large SOT effects, the SOT switching current used to flip the cell is not necessary to increase even with effective thickness increase for the data storage layer. When the insertion 2005 is below a continue layer (e.g <0.5 nm), the structure of 2005 and 2006 can be repeatable a couple of time to further increase of the effective thickness of the data storage layer while maintaining the perpendicular magnetic orientation of the whole composite layer structure. For example, the whole composite structure can be as CoFe₆₀B₂₀ 0.8 nm/Ta (or W) 0.2 nm/CoFe₆₀B₂₀ 0.8 nm/Ta (or W) 0.2 nm/CoFe₆₀B₂₀ 1 nm/MgO (tunneling barrier)/reference layer.

Since the write and read to this SOT-MRAM cell is very similar to what has been described already in FIG. 1A already, there is no need for repeating further.

FIG. 2B illustrates one embodiment of the proposed SOT-MRAM cells based on perpendicular TMR stack locating on the top of the cell structure, together with side bias magnet along the leads (can be place either on top or at the bottom of leads) of the cell for providing bias field and reducing the lead resistance. The comparison between FIG. 2B and FIG. 2A is very similar to FIG. 1B and FIG. 1A. Beneath the lead 2107, on both side of the cell structure, there are bias magnets 2111 with its magnetization 2113 pointing along the direction of switching current 2108. Below the 2111 are highly conductive assistant leads 2112, which help to reduce the lead resistance. Seed layer and the switching current lead 2107, which carries SOT current 2108, is made of metal capable of introducing large SOT effects such as those with large Magnetic Hall Effects, e.g. β-Ta, β-W, Pt, Ir, Os, Re, Hf, Pd, Rh, Mo, Nb, Zr, Au, Tc, Cd, Pb, Sn, or their alloys. The current lead 2107 links at one end to cell access/selection electronics 2110 and at the other end to the writing current supplier and control electronics 2109. Over 2107 is composite layer structure, comprising perpendicular magnetic stabilization layer 2106, non-magnetic metal insertion 2105 and perpendicular data storage layer 2104. The tunneling barrier 2103 e.g. MgO, is over the layer 2104. Over the tunneling barrier is magnetization fixed perpendicular reference layer (or layer structure) 2102, which has a capping layer 2101 to protect it during wafer process. The capping layer 2101 is linked to 2014—read current/voltage supplier and read control electronics. In terms of individual material choice and its functionality for each layers and component, similarity can be found as in FIG. 2A. Particularly, the insertion 2105 can be a continue layer capable of introducing ferromagnetic RKKY coupling between layers 2104 and 2106. 2105 also can be a very thin and rough layer or even a broken (non-continue) layer such as Ta, W or Pt below 0.8 nm, which depends on either orange peel coupling or direct ferromagnetic coupling through broken atomic layer between 2104 and 2106 layer to ensure the magnetization within layer 2104 and 2106 follow each other at the same direction at any given time. Such a design effectively increases the total thickness of the data storage layer, which not only greatly increase the thermal stability of the data storage layer, but also is potentially capable of increasing the TMR ratio of the perpendicular TMR stack, including reference layer 2102, tunneling barrier 2103 and composite layer structure including 2104, 2105 and 2106. With the material of the insertion layer is chosen to be similar to the material of the metal layer with large SOT effects, the SOT switching current used to flip the cell is not necessary to increase even with effective thickness increase for the data storage layer. When the insertion 2105 is below few atomic layers (e.g <0.6 nm), the structure of 2105 and 2106 can be repeatable a couple of time to further increase of the effective thickness of the data storage layer while maintaining the perpendicular magnetic orientation of the whole composite layer structure.

Since the write and read to this SOT-MRAM cell is very similar to what has been described already in FIG. 1A already, there is no need for repeating further.

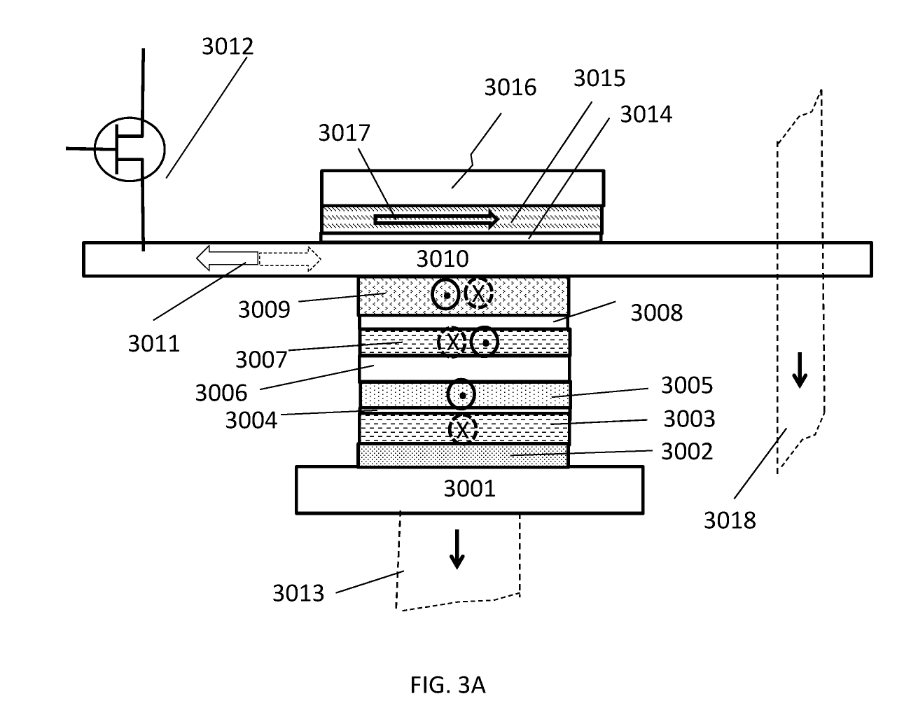

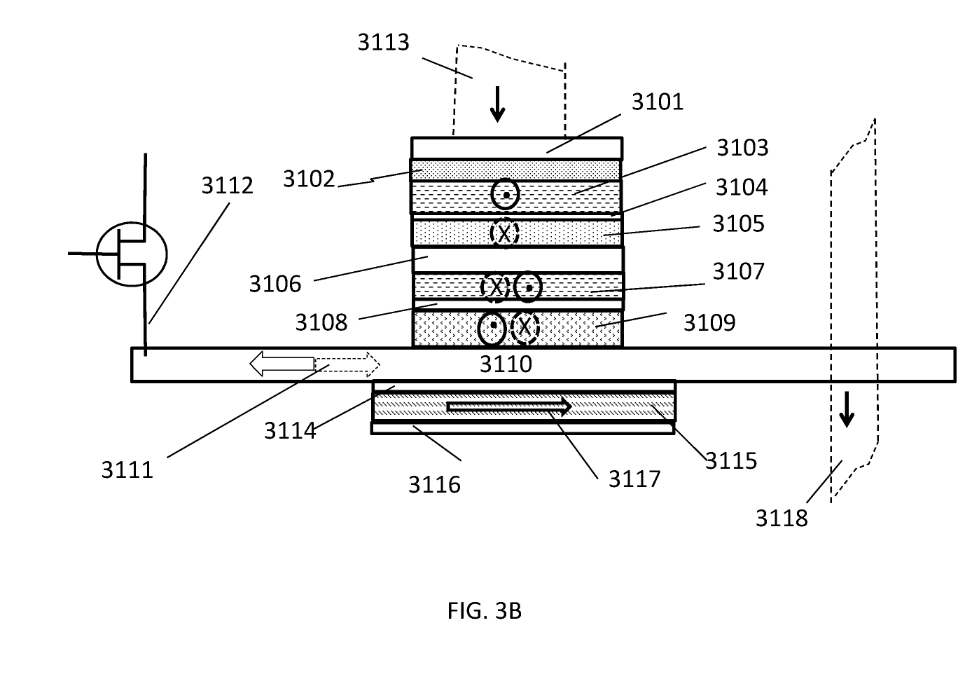

FIG. 3A illustrates one embodiment of the proposed SOT-MRAM cells based on in-plane TMR stack locating at the bottom of the cell structure. The easy axis of all its magnetic layers is in-plane and normal to the switching current direction. As shown in FIG. 3A, the whole SOT-MRAM cell is built on metallic bottom lead and seed layer 3001, which is linked to read current/voltage supplier and read control electronics 3013. Over 3001 is an antiferromagnetic layer 3002 such as IrMn, over which are in-plane so-called artificial antiferromagnetic structure comprising pinned ferromagnetic layer 3003, Ru layer 3004, and reference magnetic layer 3005. The magnetization of 3003 and 3005 all stay in the growth plane as indicated by the arrow pointing normal to the paper but pointing opposite. The Ru thickness is selected in such a way that it introducing antiferromagnetic RKKY coupling between 3003 and 3005. The whole structure including 3002, 3003, 3004 and 3005 forms the bottom reference layer structure for the memory stack. Above reference layer 3005 is the tunneling barrier 3006, over which is a composite layer structure including data storage layer 3007, non-magnetic insertion 3008, and magnetic stabilization layer 3009. The magnetization of 3007 and 3009 also stay in the growth plane but opposite to each other and with easy axle normal to the paper as indicated here but double pointing arrows. The easy axle can be induced by material choice such as add NiFe insertion in 3009 and/or 3007 for induced anisotropy or buy shape anisotropy or both. The 3008 can be Ru, or Pt, or β-Ta, or β-W, or other heavy metals capable of introducing either antiferromagnetic RKKY coupling or simple magnetostatic coupling between 3009 and 3007 to ensure their magnetization pointing to opposite direction. The presence of the 3009 helps to stabilize the magnetization in 3007 against thermal agitation hence improves the thermal stability of the cell. It also helps to fully or partially cancel the magnetic flux emitted from the cell, which enable current cell design capable of the high areal density MRAM design. Over the layer 3009 is the switching current lead 3010, which is made of metal capable of introducing large SOT effects such as those with large Magnetic Hall Effects, e.g. β-Ta, β-W, Pt, Ir, Os, Re, Hf, Pd, Rh, Mo, Nb, Zr, Au, Tc, Cd, Pb, Sn, or their alloys. The current lead 3010 links at one end to cell access/selection electronics 3012 and at the other end to the writing current supplier and control electronics 3018. During write process, when the switching current 3011 changes from left to right and or vice versa, the magnetization of the layer 3009 is changed accordingly based on SOT effect. Since the 3009 is closely anti-ferromagnetically coupled with data storage layer 3007, the magnetization of the data storage layer 3007 is also switched accordingly, hence the information stored within this kind of SOT-MRAM cell. During the read process, the reading current through the SOT-MRAM cell from lead 3013 to top lead 3010 through tunneling barrier 3006. The relative magnetization orientation between the fixed magnetic reference layer 3005 and data storage layer 3007 determinates the output voltage from the cell either high or low, which is used to figure out the storage magnetic bit within the particular cell.

It is notable that there is a bias magnet 3015 with its magnetization 3017 along the switching current direction 3011, which can be made of either a hard magnetic material, such as CoPt with corresponding seed layer or a soft-magnetic/antiferromagnetic bilayer such as CoFe/IrMn. The end magnetic charge of the bias magnet 3015 provides a magnetic field bias to the layer 3009 and 3007 also help them align normal to the current direction as shown here.

FIG. 3B illustrates one embodiment of the proposed SOT-MRAM cells based on in-plane TMR stack locating on the top of the cell structure, with the easy axis of all its magnetic layers in-plane and normal to the switching current direction. Since the layer structure for cell design in FIG. 3B is so much similar to FIG. 3A apart from the fact that the FIG. 3A is based on a so-called bottom pinned or bottom TMR stack while FIG. 3B is based on a so-called top pinned or top TMR stack. In the FIG. 3B, all the component/layer/structure labelled as 31AB (A and B represent two number range from 0 to 9) has more or less identical functionality and material choice as its counterpart 30AB in FIG. 3A. For example, 3110 (e.g. A=1 and B=0) in FIG. 3B has the same functionality and material choice as 3010 in FIG. 3A as switching current carrying lead. For the sake of similarity, no further description is needed here to understand how the cell works for any skilled people in the field while giving the drawing as FIG. 3B to show an alternative embodiment for the SOT-MARM cell design.

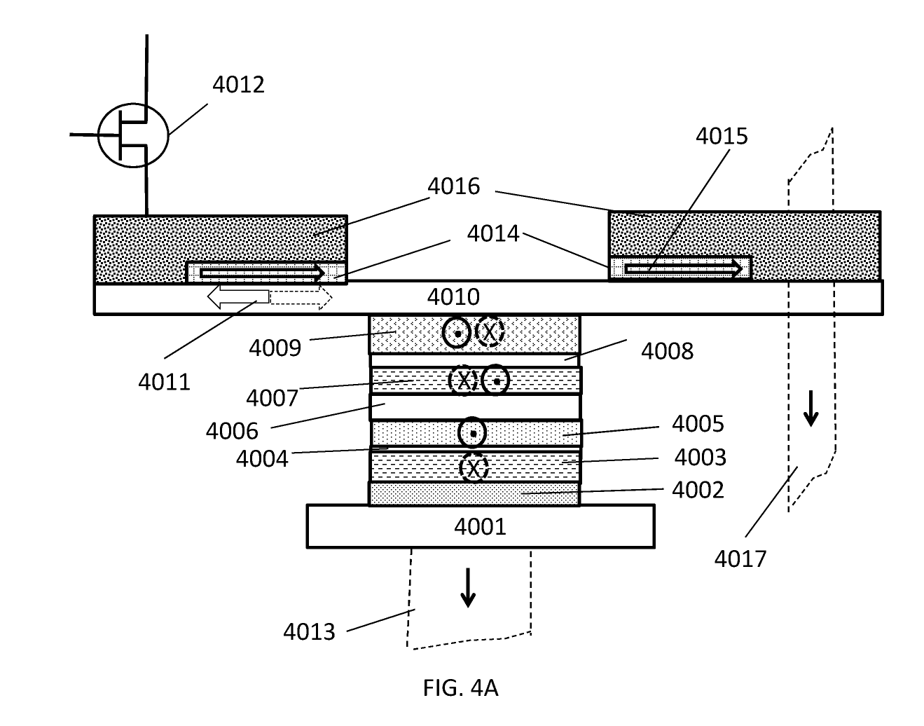

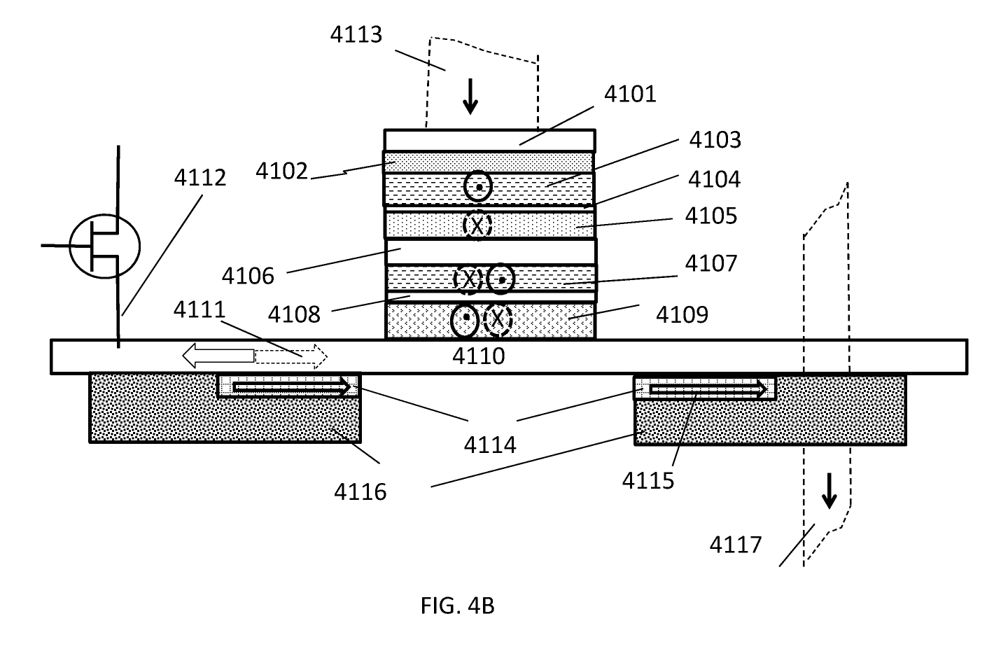

FIG. 4A illustrates one embodiment of the proposed SOT-MRAM cells based on in-plane TMR stack locating at the bottom of the cell structure, with the easy axis of all its magnetic layers in-plane and normal to the switching current direction. There is a side bias magnet 4014 with its fixed magnetization 4015 pointing along the leads of the cell for providing bias field and reducing the lead resistance. By comparing FIG. 4A with FIG. 3A, it is easy to find out that the cell structure design is identical for those between switching lead 4010 and bottom lead 4001 in FIG. 4A vs. those between switching lead 3010 and bottom lead 3001. In other words, for all the component /layer/structure labelled as 40AB (A and B represent two number range from 0 to 9) has identical functionality and material choice as its counterpart 30AB in FIG. 3A. The difference between FIG. 4A and FIG. 3A is that the bias magnet 4014 in FIG. 4A locates on the both sides of the functional TMR stack. Over the 4014 are highly conductive assistant leads 4015, which help to reduce the lead resistance. The current lead 4010 links at one end to cell access/selection electronics 4012 and at the other end to the writing current supplier and control electronics 4017. For any skilled people in the field, the writing and reading mechanism is similar to what has been described already in FIG. 3A.

FIG. 4B illustrates one embodiment of the proposed SOT-MRAM cells based on in-plane TMR stack locating at the top of the cell structure, with the easy axis of all its magnetic layers in-plane and normal to the switching current direction. There is a side bias magnet 4114 with its magnetization 4115 pointing along the leads of the cell for providing bias field for data storage layer structure including 4109, 4108 and 4107. It also helps to reduce the lead resistance. Since the layer structure for cell design in FIG. 4B is so much similar to FIG. 4A apart from the fact that the FIG. 4A is based on a so-called bottom pinned or bottom TMR stack while FIG. 4B is based on a so-called top pinned or top TMR stack. In the FIG. 4B, all the component/layer/structure labelled as 41AB (A and B represent two number range from 0 to 9) has more or less identical functionality and material choice as its counterpart 40AB in FIG. 4A. For example, 4110 (e.g. A=1 and B=0) in FIG. 4B has the same functionality and material choice as 4010 in FIG. 4A as switching current carrying lead. For the sake of the similarity, no further description is needed here to understand how the cell works for any skilled people in the field while giving the drawing as FIG. 4B to show an alternative embodiment for the SOT-MARM cell design.

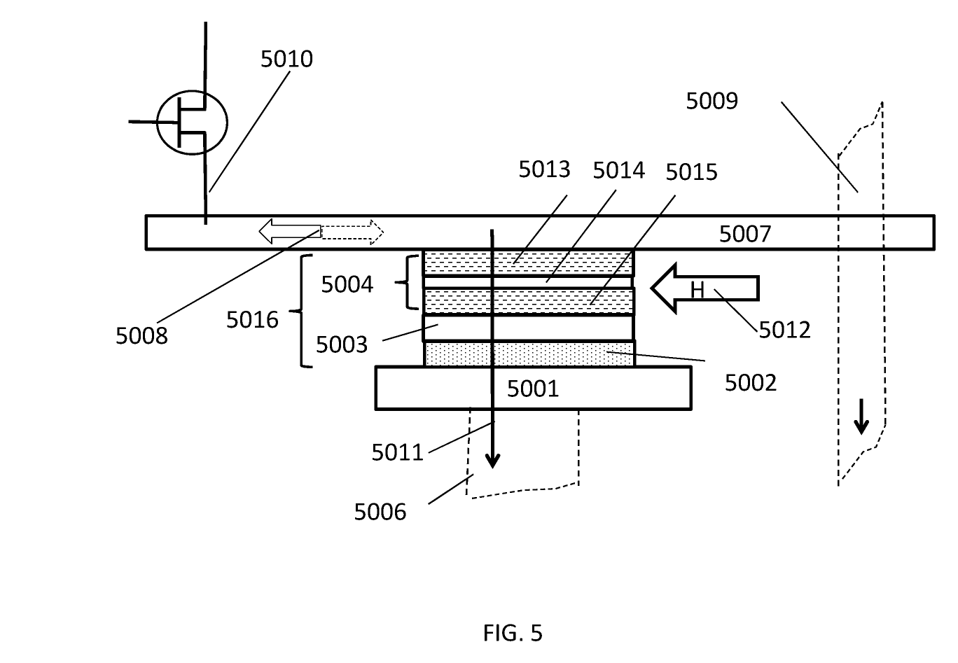

Despite of different appearance shown in the memory cell designs in FIG. 1A to FIG. 4B, there are some very key common features and characteristics shared among them. FIG. 5 illustrates the embodiment of memory cell structure, which includes all of the common features for the embodiments shown in designs from FIG. 1A to FIG. 4B. Firstly, the memory cell has a magnetization-fixed reference layer 5002, a tunneling barrier 5003, and a composite magnetic free layer (namely magnetic data storage layer) 5004, which composes at least two separated magnetic layers 5013 and 5015 and a non-magnetic space layer 5014. The magnetization configuration of the composite data storage layer 5004 can be flipped between two orientations, either parallel (digital “0”) or anti-parallel (digital “1”), to the magnetization-fixed reference layer 5002. The magnetization-fixed reference layer 5002, the tunneling barrier 5003, and the composite data storage layer 5004 forms a structure namely tunneling magnetoresistive (TMR) stack 5016, which is used to sensor the magnetization orientation of the composite data storage layer 5004 respect to the magnetization-fixed reference layer 5002 through a sensing current 5011 flowing through the TMR stack. Adjacent to the composite data storage layer 5004, there is a heavy metal current-carrying leads 5007 on the other side of the tunneling barrier. In other words, the composite data storage layer 5004 is sandwiched between heavy-metal layer 5007 and tunneling barrier 5003. The switching current, also known as memory cell writing current 5008 and switchable from two different directions as indicated by the double-end arrow, is used to flip the magnetization orientation of the composite data storage layer 5004. The memory cell has a structure or mechanism to provide a magnetic field bias 5012 to the composite data storage layer 5004 with a direction preferably parallel to the direction of the switching current 5008. The whole TMR stack 2016 is sandwiched between the layer 5007 and sensing current lead 5001, adjacent to the magnetization-fixed reference layer 5002. The sensing current lead 5001 connect to external structure of the memory cell via lead 5006, while the heavy metal current-carrying leads 5007 links to the external structure of the memory cell through 5010 and 5009 for cell accessing, switching and sensing control. All in all, the independent sensing and writing paths, the composite data storage layer together with the bias magnetic field for the data storage layer form a common feature for the new designs presented in this patent disclosure.

What is claimed is:

1. A memory cell, with independent write and read paths, comprising:
At least a composite magnetic data storage layer, sandwiched between a non-magnetic heavy metal layer and a dielectric tunneling layer, whose magnetization is switchable between two opposite orientations by an in-plane cell writing current capable of being pulsed in two different directions within said heavy metal layer;
At least a magnetization-fixed reference layer, located adjacent to and on the other side of said dielectric tunneling layer, combining with said composite magnetic data storage layer and said dielectric tunneling layer to form a tunneling magnetoresistive (TMR) stack used to sense the magnetization orientation of the data storage layer with respect to the magnetization orientation of the reference layer via sensing current through said dielectric tunneling layer;
At least a magnetic structure to provide an in-plane lateral bias magnetic field to said composite magnetic data storage layer.

2. (canceled)

3. The memory cell of claim 1, wherein said non-magnetic heavy metal layer is made of either Pt, or Pd, or Ir, or Re, or Rh, or β-Ta, or Os, or β-W, or Hf, or Ag, or V, or Cr, or Cd , or Mo, or Nb, or Zr, or Au, or Tc, or Pb, or Sn, or the alloys of the above mentioned heavy metal.

4. The memory cell of claim 1, wherein said tunneling magnetoresistive (TMR) stack is a perpendicular TMR stack with a perpendicular composite magnetic data storage layer.

5. The memory cell of claim 4, wherein said perpendicular composite magnetic data storage layer comprises at least a non-magnetic metal layer sandwiched between two ferromagnetic layers.

6. The memory cell of claim 5, wherein said non-magnetic metal layer is either a continue layer or a broken layer without physically separating the two magnetic layers.

7. The memory cell of claim 5, wherein said non-magnetic metal layer introduces ferromagnetic coupling between said two ferromagnetic layers through either Ruderman-Kittel-Kasuya-Yosida (RKKY) coupling, or orange peel coupling, or direct ferromagnetic coupling.

8. The memory cell of claim 5, wherein said non-magnetic metal layer is made of either Cr, or Pt, or V, or Pd, or Ir, or Re, or Rh, or β-Ta, or Os, or β-W, or Hf, or Ag, or Cd , or Mo, or Nb, or Zr, or Au, or Tc, or Pb, or Sn, or the alloys of the above mentioned metal.

9. The memory cell of claim 1, wherein said tunneling magnetoresistive (TMR) stack is an in-plane TMR stack with an in-plane composite magnetic data storage layer.

10. The memory cell of claim 9, wherein said in-plane composite magnetic data storage layer comprises at least a non-magnetic metal layer sandwiched between two ferromagnetic layers.

11. The memory cell of claim 10, wherein said non-magnetic metal layer introduces antiferromagnetic coupling between said two ferromagnetic layers through either Ruderman-Kittel-Kasuya-Yosida (RKKY) coupling or magnetistatic coupling

12. The memory cell of claim 10, wherein said non-magnetic metal layer is made of either Cr, or Pt, or V, or Pd, or Ir, or Re, or Rh, or β-Ta, or Os, or β-W, or Hf, or Ag, or Cd , or Mo, or Nb, or Zr, or Au, or Tc, or Pb, or Sn, or the alloys of the above mentioned metal.

13. The memory cell of claim 9, wherein said in-plane composite magnetic data storage layer has anisotropy, induced by either anneal induced anisotropy or shape anisotropy, or both, normal to the switching current direction.

14. (canceled)

15. (canceled)

16. (canceled)

17. (canceled)

18. (canceled)

19. (canceled)

20. (canceled)
